(19) United States
(12) Patent Application Publication
(10) Pub. No.: US 2014/0321862 A1
(43) Pub. Date: Oct. 30, 2014

(54) PHOTON DETECTOR AND A PHOTON DETECTION METHOD

(71) Applicant: Kabushiki Kaisha Toshiba, Minato-ku (JP)

(72) Inventors: Bernd Matthias FROHLICH, Cambridge (GB); Iris Choi, Cambridge (GB); James Dynes, Cambridge (GB); Zhiliang Yuan, Cambridgeshire (GB); Andrew James Shields, Cambridge (GB)

(73) Assignee: Kabushiki Kaisha Toshiba, Minato-ku (JP)

(21) Appl. No.: 14/155,639

(22) Filed: Jan. 15, 2014

(30) Foreign Application Priority Data
Apr. 26, 2013 (GB) 1307584.1

(51) Int. Cl. H04L 7/00; H01L 31/107

(52) U.S. Cl. CPC H04L 7/0075; H01L 31/107
USPC 398/154; 250/214 R; 250/214.1; 398/202

(57) ABSTRACT

A photon detection system is provided comprising a photon detector, configured to detect photons during intervals when in a receiving state and to output a signal when a photon is received, a controller, configured to generate a time varying gating signal wherein said gating signal switches said detector between the receiving state and a non-receiving state, said controller being configured to receive and process information relating to the times photons are expected to arrive at said detector, the controller being configured to generate the gating signal such that the photon detector is in the receiving state for intervals when photons are expected and also in the receiving state for additional intervals between the intervals when the photons are expected; a detection module, configured to distinguish between when the output signal from the photon detector corresponds to an interval when photons are expected and said additional intervals.

### FIELD

Embodiments described herein relate generally to the field of photon detectors and photon detection methods.

### BACKGROUND

There is a need in a number of applications for photon detectors that can detect single photons. Single photon detectors are used in quantum communication systems, where information is sent between a transmitter and a receiver in the form of single quanta, such as single photons. An example of quantum communication is quantum key distribution (QKD), which results in the sharing of cryptographic keys between two parties.

Avalanche photodiodes (APDs) are able to detect single photons when biased above their breakdown voltage. An incoming photon is absorbed and generates an electron-hole pair, which is separated by the electric field inside the APD. Due to the high electric field the electron or hole may trigger an avalanche of excess carriers causing a detectable current flow.

Following a photon count, detectors can show an increased probability of registering another count in a later gate. These counts are called afterpulses. Some detection devices, such as InGaAs avalanche photodiodes, have a high probability of generating an afterpulse, due to charge carriers being trapped by defects following an avalanche. These trapped carriers can trigger a second avalanche in a later detection gate, which leads to unwanted counts, known as afterpulses. These afterpulse counts contribute to the total detection rate which can lead to prohibitively high error counts in applications such as QKD.

### BRIEF DESCRIPTION OF THE DRAWINGS

Embodiments will now be described with reference to the following figures:

FIG. 1a illustrates the photon detection probability for a gated photon detector where the frequency of the light signal incident on the gated photon detector is the same as the detector gating frequency;

FIG. 1b illustrates the photon detection probability for a gated photon detector where the frequency of the light signal incident on the gated photon detector is the same as the detector gating frequency and the photon detector operates with a longer gate time;

FIG. 2 illustrates the photon detection probability for a photon detection system in accordance with an embodiment;

FIG. 3a is a schematic of a quantum communication system comprising a photon detection system in accordance with an embodiment, where the photon detection system comprises a gated photon detector, a discriminator and an afterpulse separation module;

FIG. 3b is a schematic of a quantum communication system comprising a photon detection system in accordance with an embodiment, where the afterpulse separation is implemented before the discriminator;

FIG. 3c is a schematic of a quantum communication system comprising a photon detection system in accordance with one embodiment, where the quantum communication system comprises a master clock;

FIG. 4a is a schematic of an AND gate which separates events occurring in the illuminated gates from events occurring in the non-illuminated gates;

FIG. 4b is a schematic of an afterpulse separation module where the separation is performed with a fast switch;

FIG. 5 is a schematic of a photon detection system in accordance with an embodiment, comprising a self differencing circuit;

FIG. 6 is a schematic of a quantum communication system comprising a photon detection system in accordance with an embodiment.

### DETAILED DESCRIPTION

According to one embodiment, a photon detection system is provided comprising a photon detector, configured to detect photons during intervals when it is in a receiving state and to output a signal when a photon is received, a controller, configured to generate a time varying gating signal wherein said gating signal switches said detector between the receiving state and a non-receiving state, said controller being configured to receive and process information relating to the times photons are expected to arrive at said detector, the controller being configured to generate the gating signal such that the photon detector is in the receiving state for intervals when photons are expected and also in the receiving state for additional intervals between the intervals when the photons are expected, a detection module, configured to distinguish between when the output signal from the photon detector corresponds to an interval when photons are expected and said additional intervals.

A receiving state is a high sensitivity state, and can be thought of as an “on” state. A non-receiving state is a low sensitivity state and can be thought of as an “off” state. In an embodiment, in the receiving state the sensitivity of the photon detector is 100 times higher than during the non-receiving state. In a further embodiment, in the receiving state the sensitivity of the photon detector is 1000 times higher than during the non-receiving state. In one embodiment, the receiving state for an APD is the state in which any part of the APD is biased above breakdown.

In one embodiment, the gating signal is a signal that has half wave symmetry. It may be a sinusoidal wave or a square wave signal. In one embodiment, the frequency of the gating signal is at least 10 MHz. In a further embodiment, the frequency of the gating signal is higher than 100 MHz. In one embodiment, the frequency of the gating signal is an integer multiple of the frequency at which photons are expected to arrive at the detector.

In one embodiment, the detection module comprises a discriminator configured to output an electrical pulse if an input signal exceeds a voltage threshold.

In one embodiment, the detection module is configured to output a pulse when the output signal from the photon detector corresponds to an interval when photons are expected. In one embodiment, the detection module comprises a first output and a second output. In a further embodiment, it is configured to output a pulse from the first output when the output signal from the photon detector corresponds to an interval when photons are expected and is further configured to output a pulse from the second output when the output signal from the photon detector corresponds to an additional interval. In a further embodiment, it is configured to output a pulse from the first output when the output signal from the photon detector corresponds to an interval when photons are expected and is further configured to output a pulse from the second output when the output signal from the photon detector does not correspond to an interval when photons are expected.

In one embodiment, the photon detector is based on an avalanche photodiode. It may be an APD based on Indium Gallium Arsenide, Silicon, Germanium, or Gallium Nitride. In one embodiment, the APD is optimised for single-photon detection. In one embodiment the APD is optimised for Geiger mode operation. In one embodiment, the single photon detection efficiency of the APD is higher than 10%. In one embodiment, the breakdown voltage of the APD is less than 100V at 20 degrees Celsius.

In one embodiment, the photon detection system comprises a biasing circuit configured to reverse bias the avalanche photodiode, the biasing circuit comprising a DC voltage bias supply; and an AC voltage bias supply. In one embodiment, the AC voltage bias supply may output an AC voltage signal which has half wave symmetry. The AC voltage bias supply may be configured to output an AC voltage in the form of a square wave or sinusoidal wave. In one embodiment, the AC voltage signal has an amplitude larger than 1 Volt. In a further embodiment, the AC voltage signal has an amplitude in the range of 4-12V. In one embodiment, the APD bias voltage is above the APD breakdown voltage at its highest value and below the APD breakdown voltage at its lowest value during each gating period.

In one embodiment, the photon detection system further comprises a signal divider, configured to divide a signal into a first part and a second part, where the first part is substantially identical to the second part, and further comprises a delay means configured to delay the second part with respect to the first part by an integer multiple of the period of said gating signal, and still further comprises a combiner configured to combine the first and delayed second parts of the signal such that the delayed second part is used to cancel periodic variations in the first part.

A photon detection system of the type discussed above may be provided in a receiver for a quantum communication system configured to receive light pulses encoded using a basis selected from at least two bases and comprising a decoder configured to perform a measurement in a basis selected from the possible bases used to encode the pulses. The photon detection system of the type discussed above may be configured to receive the output of the decoder.

A receiver of the type discussed above may be provided in a quantum communication system comprising a sending unit configured to send light pulses encoded using a basis selected from at least two bases and a communication channel configured to communicate information relating to the times photons are expected to arrive at the detector between the sending unit and the receiver.

According to one embodiment a method of photon detection is provided, the method comprising providing a photon detector configured to detect photons when in a receiving state and to output a signal when a photon is received, receiving and processing information relating to the times photons are expected to arrive at said detector, generating a time varying gating signal and applying said time varying gating signal to said photon detector such that the photon detector is in the receiving state for intervals when photons are expected and also in the receiving state for additional intervals between the intervals when the photons are expected and distinguishing between when the output signal from the photon detector corresponds to an interval when photons are expected and said additional intervals.

In one embodiment, the method of photon detection includes a method of discriminating the signal from the photon detector, or discriminating the signal from the detection module, which involves outputting an electrical pulse if an input signal exceeds a voltage threshold.

In one embodiment, the method of distinguishing involves outputting a pulse when the output signal from the photon detector corresponds to an interval when photons are expected. In a further embodiment, it involves outputting a pulse from a second output when the output signal from the photon detector corresponds to an additional interval.

In one embodiment, the photon detection method involves dividing the output signal of the photon detector into a first part and a second part, where the first part is substantially identical to the second part, and further involves delaying the second part with respect to the first part and combining the first and delayed second parts of the signal such that the delayed second part is used to cancel periodic variations in the first part of the output signal. The second part of the signal is delayed by an integer multiple of the period of the detector gating signal. In a further embodiment, one part of the signal is inverted with respect to the other part of the signal prior to combining the two parts of the signal.

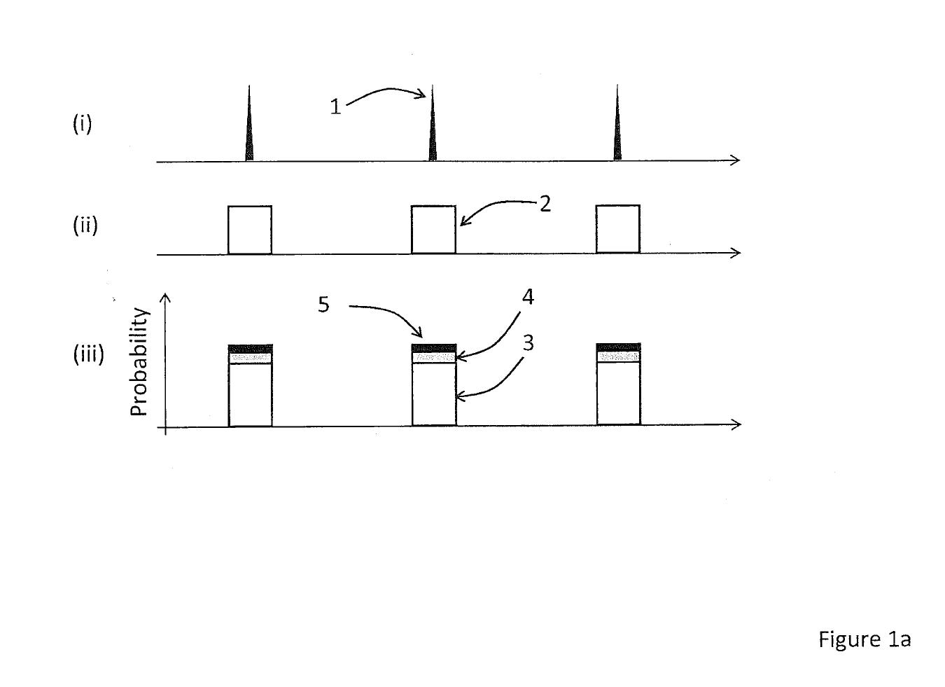

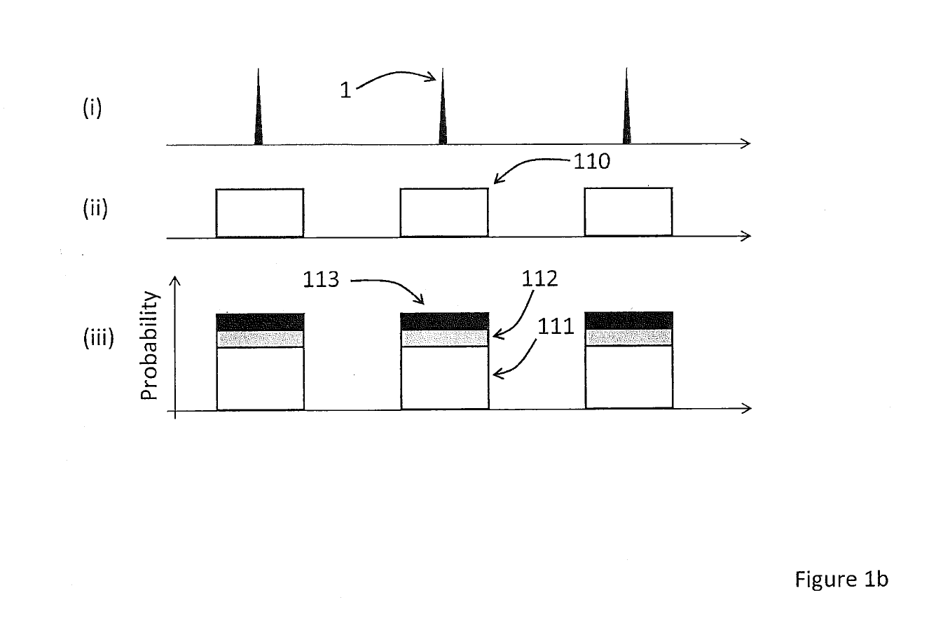

FIG. 1a(i) shows a repeating light signal 1 which is incident on a gated photon detector. For these figures, the x axis variable is time. The light signal 1 consists of regularly timed pulses of light. The repetition rate is the light signal frequency. The detector is periodically switched between a receiving state and non-receiving state at the gating frequency. A time interval during which the detector is in a receiving state is called a detection gate. For a detector based on an APD, the APD is biased above the breakdown voltage when switched to the receiving state and below the breakdown voltage when switched to the non-receiving state. Operation of APDs above breakdown is called Geiger mode. APDs can also be operated below breakdown but are then much less sensitive.

FIG. 1a(ii) shows the detector gate timing. A gate is the time interval that the detector is in the receiving state. These gates are regularly repeated, such that a light pulse from FIG. 1a(i) coincides with each detector gate. The detector can be any gated photon detector having a non-zero afterpulse probability. The photon detector shown here operates with a detection frequency which is identical to the gating frequency of the detector. The frequency of the incidence of the repeating light signal 1 on the gated photon detector, the light signal frequency, is the same as the gating frequency of the detector in this case.

A count occurs if a signal is received during a gate, indicating a detected photon, a dark count, or an afterpulse. In other words, when the detector outputs an electrical signal, it indicates that either a detected photon, a dark count or an afterpulse has occurred. Even if no photon was incident on the detector it can register a count due to thermal effects. These counts are called dark counts. Following a photon count some detectors show an increased probability of registering another count in a later gate. These counts are called afterpulses. Afterpulses can occur following a dark count or an afterpulse. However, the afterpulse probability here is defined relative to the number of detected photons only, i.e. the afterpulse probability is equal to the number of afterpulses divided by the number of photon counts. They are especially prominent in avalanche photodiodes, where charge carriers can be trapped by defects following an avalanche, and these charges can get released in one of the following gates.

Afterpulses also occur in photomultiplier tube based detectors, due to various processes, such as the accelerated electrons ionising residual gases in the photomultiplier tube, or back scatter of electrons at the dynodes.

FIG. 1a(iii) shows the probability of a count during a detection gate, which is made up from three components: the photon detection probability 3 depending on the detector efficiency and the intensity of the incident light signal; the dark count probability 4 corresponding to the probability to measure a count without any light incident on the detector; and the afterpulse probability 5. The afterpulse probability 5 is the probability to measure an extra count due to afterpulsing if a photon was detected in one of the preceding detection gates.

The afterpulse probability 5 is dependent on the length of the detection gates. The longer the gate time of the detector the higher is the chance that the release of a trapped carrier leads to an afterpulse count. Trapped carriers are released at random times after an avalanche due to thermal excitation with a probability which decreases with time. Therefore, a carrier can be released when the detector is in the receiving state as well as when it is in the non-receiving state. If the carrier is released when the detector is in a receiving state, it can cause an afterpulse. The higher the ratio of the length of the intervals that the detector is in the receiving state to the length of the intervals that the detector is in the non-receiving state, the more released carriers will cause an afterpulse. Longer gate times, that is longer times that the detector is in the receiving state, can also lead to higher avalanche currents which in turn lead to more trapped carriers in the detector and therefore also to more afterpulse counts.

In the case shown in FIG. 1a, the afterpulse probability 5 is reduced by using short detection gates. The detector is switched into a receiving state for a short time and then kept in a non-receiving state for a longer time.

This can be implemented directly with the driving signal or gating signal of the APD. The detector is switched between a receiving state and a non-receiving state, where the gating signal is such that the detector is in the non-receiving state for a longer time. By this, it is understood to mean that the detector is in the non-receiving state for longer intervals than it is in the receiving state. In other words, the gate length is shorter than the length of time between the gates. The gate length may be of the order of nanoseconds, for example 1 ns. The time between the gates may be of the order of 100 ns to 1 μs.

FIG. 1b(i) shows a repeating light signal 1 which is incident on a gated photon detector. The frequency of the repeating light signal in this case is the same as that of FIG. 1a(i).

FIG. 1b(ii) shows the detector gate timing. The photon detector here also operates with a periodic gating signal such that a light pulse from FIG. 1b(i) coincides with each detector gate. However, in this case, the detector is switched between a receiving state 110 and a non-receiving state such that the intervals that the detector is in the receiving state 110 are the same length of time as the intervals that the detector is in the non-receiving state. In other words, the length of the detection gates is the same as the length of the intervals between the detection gates. The detector in this case is in the receiving state 110 for longer time intervals than the case shown in FIG. 1a(ii).

FIG. 1 b(iii) shows the probability of a count during a detection gate, which is made up from three components: the photon detection probability 111 depending on the detector efficiency and the intensity of the incident light signal; the dark count probability 112 corresponding to the probability to measure a count without any light incident on the detector; and the afterpulse probability 113.

Because the afterpulse probability 113 is dependent on the length of the detection gates, and the length of the detection gates in this case is longer than the length of the detection gates in the case shown in FIG. 1a(ii), there is a higher chance that the release of a trapped carrier leads to an afterpulse count. Therefore the afterpulse probability 113 is larger than the afterpulse probability 5. Longer gate times can also lead to higher avalanche currents which in turn lead to more trapped carriers in the detector and therefore also to more afterpulse counts. The dark count probability 112 should also be larger than the dark count probability 4 as there is a higher chance that a thermal excitation leads to a count.

The use of the gating signal for which the length of the gates is the same as the length of the time intervals between the gates, where the gating frequency is the same as the light signal frequency means that the detector works well with self-differencing or sine wave gating techniques and there may be a large number of afterpulse counts.

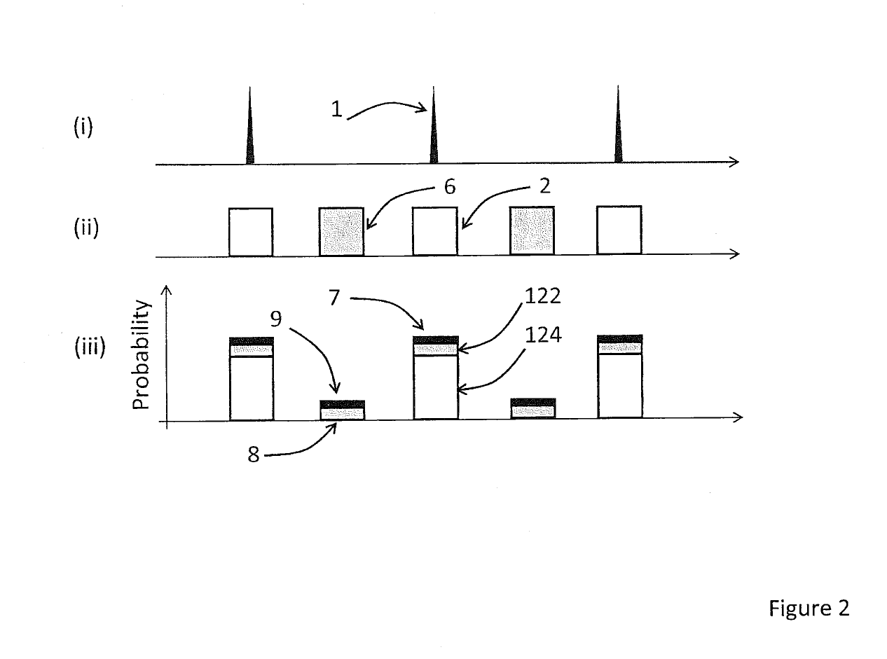

FIG. 2(i) shows a repeating light signal 1 incident on a gated photon detector. For these figures, the x axis variable is time. The light signal 1 consists of regularly timed pulses of light. The gated photon detector can be but is not restricted to gated detectors based on avalanche photodiodes made of Indium Gallium Arsenide, Silicon, Germanium, or Gallium Nitride; gated detectors based on photomultiplier tubes; gated detectors based on passive quenching, active quenching, self-differencing techniques, or sine-wave gating techniques. Self differencing techniques and sine wave gating techniques are further described later in this application.

FIG. 2(ii) shows the detector gate timing. The gate is the time interval for which the detector is in the receiving state. The gates are regularly timed, and the detector gating frequency is increased compared to that of FIG. 1a(ii). In between two light signal pulses 1 there are one or more additional detection gates 6. In other words, the photon detector operates with a periodic gating signal such that a light pulse from FIG. 2(i) does not coincide with each detector gate, but only coincides with a fraction of the gates. The detector gate timing shown in FIG. 2(ii) is such that the detector gates 2 coincide with the times of the light pulses in FIG. 2(i), and there is also one extra detection gate 6 between the light pulses. The gating frequency in this figure is two times the frequency at which photons are expected to arrive at the detector, the light signal frequency. The gating frequency may be any integer multiple of the frequency at which the photons are expected to arrive at the detector, and may be at least two times the frequency at which photons are expected to arrive at the detector. In this case, the detector is switched between a receiving state or gate, and a non-receiving state such that the intervals that the detector is in the receiving state, or gates, are the same length of time as the intervals that the detector is in the non-receiving state, between the gates. In other words, the length of the detection gates is the same as the length of the time intervals between the detection gates. The detector in this case is in the receiving state for shorter time intervals than the case in FIG. 1b(ii) but the gating frequency is increased.

When a detector is in the receiving state it is more likely to detect a photon than when it is in the non-receiving state. The receiving state can be thought of as an “on” state, and the non-receiving state can be thought of as an “off” state. A receiving state is a high sensitivity state and a non-receiving state is a low sensitivity state. In the receiving state the sensitivity of the photon detector may be 100 times higher than during the non-receiving state, or may be 1000 times higher than during the non-receiving state. The sensitivity may increase sharply to a maximum during the “on” time, or gates (when it is in a receiving state) and then decrease sharply again. The sensitivity may depend on the driving signal used, for example sine wave or square wave.

For a detector based on an APD, the APD may be biased above the breakdown voltage when switched to the receiving state and below the breakdown voltage when switched to the non-receiving state. The receiving state for an APD may be the state in which any part of the APD is biased above breakdown. Operation of APDs above breakdown is called Geiger mode. APDs can also be operated below breakdown but are then much less sensitive.

If the gating signal is a square wave, then the APD has a constant bias voltage that is higher than the breakdown voltage during the detection gates, when it is in the receiving state, or “on” state, and will be switched to a constant bias voltage that is below the breakdown voltage when it is switched to the non-receiving state, or “off state”. When the APD is biased above the breakdown voltage it is operating in Geiger mode and is capable of single photon detection.

If the gating signal is, for example, a sine wave, then the bias voltage will still be higher than the breakdown voltage during a detection gate, and lower than the breakdown voltage between the gates, however the bias voltage will not remain at a constant voltage above the breakdown voltage. The intervals when the APD is biased above the breakdown voltage are the detection gates, when the detector is in the receiving state. The intervals when the APD is biased below the breakdown voltage, between the detection gates, are those for which the detector is in the non-receiving state.

In a system where photons are emitted from a sending unit at the light signal frequency, photons are expected to arrive at the detector with the light signal frequency. In such a system, there may be provided a master clock unit. The master clock can be positioned at the receiver or sending unit. It is then transmitted to the sending unit or receiver, respectively, for synchronisation. The master clock provides a clock signal to the photon emitter. The photon emitter is configured to emit a light pulse when it receives the clock signal. The clock signal may be an electrical signal consisting of regular pulses. The clock signal may also indicate when the photons are expected to arrive at the detector. This clock signal can then be used to generate a gating signal which has a frequency which is an integer multiple of the clock signal and may be used to distinguish when a detection corresponds to an interval when a photon is expected to arrive at the detector.

In some cases, the clock signal may be regenerated after transmission. For example, the clock signal frequency may be reduced before being transmitted, and then regenerated after being received. In these cases, the signal that indicates when the photons are expected to arrive at the detector will be the signal with the original frequency, which may be the regenerated clock signal.

There may be signal losses in the transmission channel, such that a light pulse may not in fact arrive at the detector in every period of the clock signal. The signal that indicates when the photons are expected to arrive at the detector is still, in this case, the clock signal. Generally, the signal that indicates when the photons are expected to arrive at the detector covers any signal that may be used in order to synchronise the detector gating with the arrival of the light pulses. However, in a quasi continuous mode the detector gating is not synchronised with the light signal frequency, in other words the detectors and photon source are not synchronised. The light signal frequency will still indicate when photons are expected to arrive at the detector, however, the detectors will not be synchronised with the light signal. Other components in the detection module, for example, the afterpulse separation module discussed later will be synchronised using the light signal frequency however.

During the extra gates 6 no light is incident on the detector. These gates are referred to as the non-illuminated gates or as additional gates or as extra gates or additional intervals. These gates have to be distinguished from the initial gates 2 during which light is incident on the detector which are referred to as the illuminated gates. In other words, illuminated gates are detection gates during which light pulses are expected to be incident on the detector and non-illuminated gates or additional gates are detection gates during which no light pulses are expected to be incident on the detector. The frequency of the illuminated gates is the same as the frequency at which photons are expected to arrive at the detector, and the frequency at which photons are emitted at a sender unit.

FIG. 2(iii) shows the probability of measuring a count during the on time of the detector. The probability to detect a photon 124 and the dark count probability 122 are likely to be similar to the probability to detect a photon and the dark count probability without the additional non-illuminated gates. However, using a different frequency might require changes to the detector electronics and may have an effect on these probabilities. The probability to detect an afterpulse 7 might change depending on the properties of the photon detector used but will be similar to the initial afterpulse probability 5. The afterpulse probability in the extra gates 9 and the dark count probability in the extra gates 8 are likely to be similar to the probabilities in the initial gates 2. The probability to detect a photon is zero as no photons are incident on the detector during the extra gates.

Counts occurring during an illuminated gate 122, 124, 7 are distinguished and may be separated from counts occurring during a non-illuminated gate 8, 9. If the counts from non-illuminated gates are discarded, the total number of afterpulse counts is reduced to a similar level as without the extra gates. In other words, if the gating frequency is an integer multiple of the light signal frequency (gating frequency=N×light signal frequency), the counts of (1/N) of the gates (which are illuminated) are separated out and the other counts are discarded. By adding a suitable number of extra gates the gating signal can be a signal which switches the detector such that the gate length is the same as the length of time between the gates. The gating signal can therefore be made to have half wave symmetry. A suitable number of extra gates may be in the range of 100 to 1000 extra gates. However, it can be as little as one extra gate. A signal with half wave symmetry is for example a square wave signal or sine wave signal.

When a detector is gated with a signal with half wave symmetry it has approximately the same time in the receiving state as time in the non-receiving state. That is, the intervals in the receiving state are the same length of time as the intervals in the non-receiving state.

For the case of an APD, the AC voltage signal supplied to the biasing circuit may be a signal with half wave symmetry, such that the intervals that the APD is in the receiving state are the same length of time as the intervals in the non-receiving state. The AC voltage signal may be a square wave with half wave symmetry. Other examples of signals with half wave symmetry would be a sine wave, or triangle or saw-tooth signal, but it could also be another shape which is optimised to drive the detector as efficiently as possible.

Techniques such as sine-wave gating or self-differencing techniques require AC coupled components such as splitters, filters or amplifiers, which often have a limited bandwidth. These components work best with a simple periodic signal such as has been discussed above. Sine-wave gating techniques require a sine wave signal. A sine wave signal is a very clean signal with ideally only one frequency component if Fourier transformed, therefore it may allow removal of capacitive response of the APD with filters. Other techniques which require AC coupled components are techniques which work by overlapping part of the initial gating signal with the output of the APD to remove the capacitive response.

Afterpulsing may become an issue at gating frequencies above 1-10 MHz. The self-differencing technique is used particularly for high speed applications, which operate with a gating frequency of the order of 100 MHz.

The information provided by the counts 8, 9 in the extra gates can be beneficial for some applications of the photon detector. For example, the information provided by the counts in the extra gates might be used to determine an estimate of the afterpulse probability which could be useful for applications such as QKD. Depending on the properties of the photon detector there may be a reduction of the afterpulse probability in the initial gates, due to the additional gates. For example, for an APD, this could be the case if the probability to release a trapped carrier is higher when it is biased above the breakdown voltage of the detector than when it is below the breakdown. A higher voltage applied across the APD might deform the potential of the trap slightly and therefore make it easier to release the charge, depending on properties such as, for example, the APD material or the breakdown voltage.

When a photon detector operates with a periodic gating signal, for example a signal with half wave symmetry, and with additional non-illuminated gates from which counts are separated the afterpulsing probability may be reduced and additional information may be obtained from the extra gates, without any reduction of the detection frequency.

Using shorter detection gates, with additional non illuminated gates in between the detection gates leads to different characteristics of the detector for example weaker avalanches. This means the photon detection probability and the dark count probability would change.

In the detector system of FIG. 2, extra gates 6 are added to the gating signal of the detector which are non-illuminated, in other words, the gating frequency is increased, such that it is higher than the frequency at which photons are expected to arrive at the detector. The dark count probability 8 in the extra gates is the same as the dark count probability 4 in the initial gates 2. If the extra counts arising from the extra gates 6 are discarded, only the counts from the initial, illuminated gates 2 remain. The detector is provided with means to distinguish and separate counts in those extra gates from counts in the initial gates.

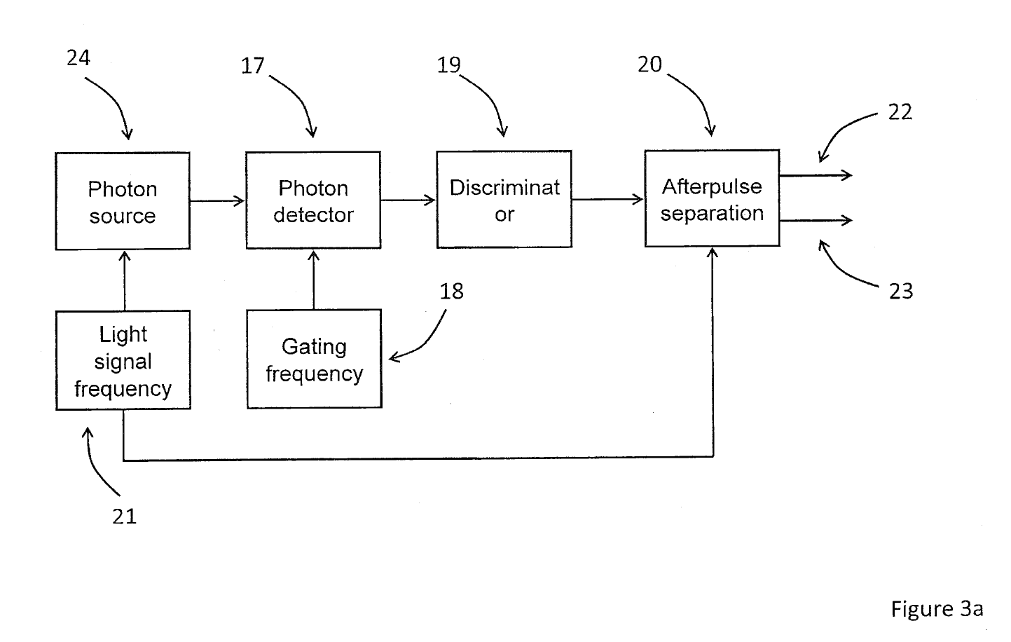

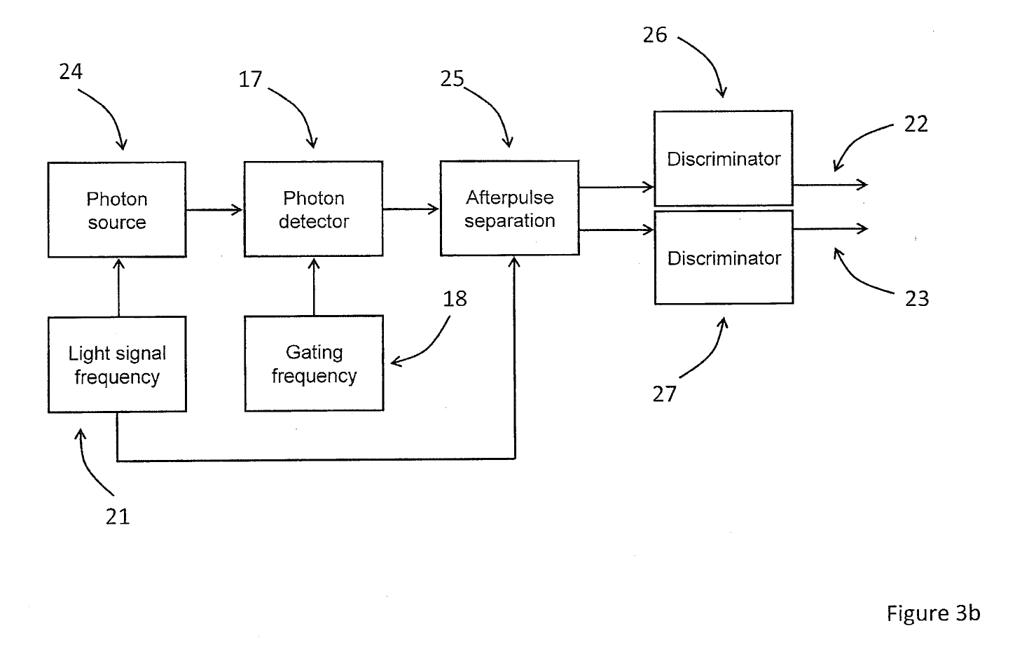

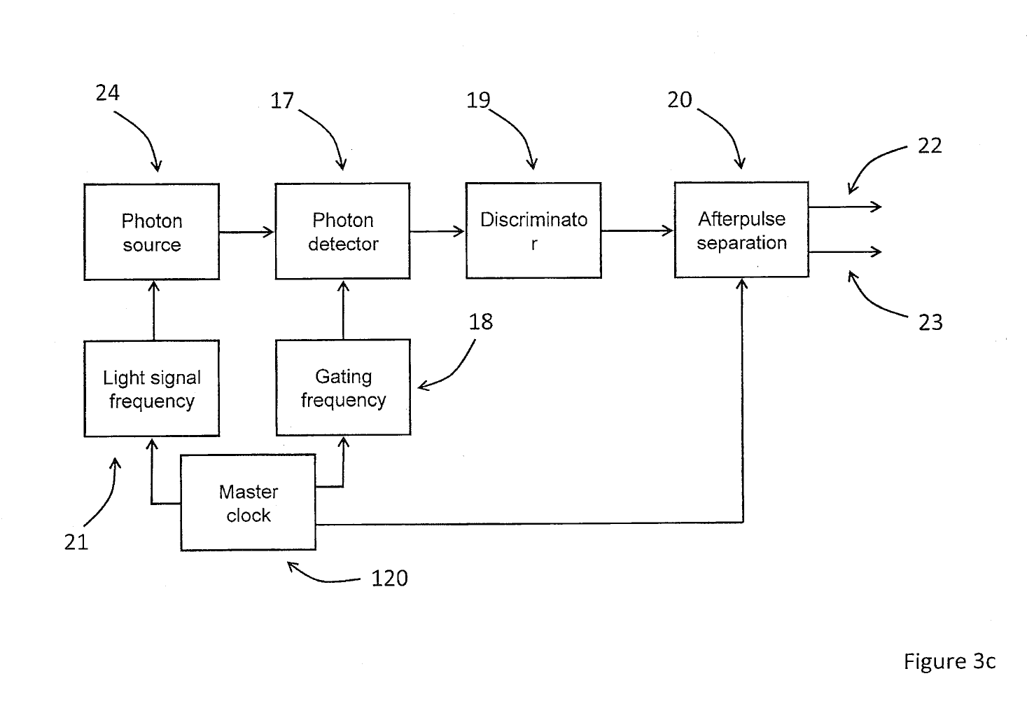

FIG. 3a shows a schematic of a quantum communication system with a photon detection system in accordance with one embodiment. A light signal frequency module 21 is connected to a photon source 24. The light signal frequency module 21 is also connected to an input of an afterpulse separation module 20. Information about the light signal frequency may be transmitted along a channel between the sender and the receiver unit. The photon source 24 is connected to a photon detector 17 via a channel. The photon source 24 may be a single photon source. The photon source 24 may be a pulsed laser diode and an attenuator. The attenuator may be set so that the average number of photons per pulse is much less than 1. The channel between the photon source 24 and the photon detector 17 may be a single photon channel, and is usually an optical fibre. Usually, both the photon channel and the light signal frequency channel are optical fibres which may be separate fibres, or fibres bound together as bundles, or a single fibre.

If the information about the light signal frequency is transmitted via an optical channel, as optical pulses, then these pulses may then be transformed into electrical pulses after transmission. These electrical pulses may then be fed into the afterpulse separation module 20 and may also be used as trigger pulses to trigger a separate set of pulse shaping electronics, which generate a pulse shape to drive the photon detector 17. That is, the information about the light signal frequency may also be used to generate the gating frequency such that it is higher than the light signal frequency, and may be used to generate the gating frequency such that it is an integer multiple of the light signal frequency.

In the case where the detector is based on an APD, there may be a biasing circuit with a DC input and an AC input which provides a gating signal for the APD. The frequency of the AC input signal may be generated from the light signal frequency such that it is higher than the light signal frequency. The frequency of the AC signal is the gating frequency. The APD may be optimised for single-photon detection. The DC and AC input are combined at a bias-T junction, and the DC level set to a level just below the breakdown voltage of the APD. In combination with the AC signal the level is switched periodically above and below the breakdown voltage. The period may be generated based on the light signal frequency such that it is higher than the light signal frequency. The output from the biasing circuit is connected to the APD. The APD bias voltage is therefore above the APD breakdown voltage at its highest value and below the APD breakdown voltage at its lowest value during each gate period. When the APD is biased above the breakdown voltage it is capable of highly sensitive photon detection and single photon detection. The AC voltage signal may have half wave symmetry. The AC voltage signal may have an amplitude larger than 1 Volt. The AC voltage signal may have an amplitude in the range 4 to 12 V. The AC voltage signal may be in the form of a square wave or sinusoidal wave.

The light signal frequency may be inputted into the gating frequency module 18. Alternatively, for example in quasi-continuous mode, the gating frequency may not be synchronised with the light signal frequency. However, the light signal frequency will still be inputted to the afterpulse separation module, in order that pulses coinciding with the light signal can be distinguished from pulses not coinciding with the light signal. The gating frequency may be increased such that the photon detectors are driven at a higher frequency than the light signal frequency. A frequency synthesizer may be used to generate a frequency multiplied version of the light signal frequency. The frequency synthesizer may be a phase locked loop. Alternatively, the gating frequency module may generate the gating frequency independently of the light signal frequency.

The gating frequency module 18 is connected to the photon detector 17. The gating frequency module 18 provides a signal to the photon detector 17 which sets the gating frequency of the photon detector 17. The output of the photon detector 17 is connected to the discriminator 19. The photon detector 17 outputs an electrical signal to the discriminator 19. The discriminator 19 is connected to the afterpulse separation module 20. The afterpulse separation module 20 has two outputs 22 and 23.

A photon source 24 is operating with a repetition rate given by the light signal frequency 21. Light from said photon source 24 is incident on gated photon detector 17 which is operated with a gating frequency 18 of f_{gate}. The gating frequency is higher than the light signal frequency. The detector gates are intervals during which photons are expected to arrive at the detector. There are also gates which are additional intervals when photons are not expected to arrive at the detector. In other words, the detector is in the receiving state for intervals which include the time at which photons from the photon source are expected to arrive at the detector. The detector is also in the receiving state for additional intervals, when no photons are expected to arrive at the detector. The detector is in the non-receiving state in between these intervals. A typical period of the gating signal is 1 ns. For a square wave signal this means the detector is above breakdown for 0.5 ns and below breakdown for 0.5 ns. The ratio of time that the detector is in the receiving state to time that the detector is in the non-receiving state may be almost equal, that is 1:1 or 1:3. However, it could be much larger ratios of 1:100 or 1:1000.

The electrical signal generated by the gated photon detector 17 is discriminated with a discriminator 19 which generates a pulse if an avalanche is registered in a gate. The simplest form of a discriminator uses a simple voltage threshold, whereby if the output from the photon detector is higher than the voltage threshold, the discriminator outputs a pulse. There are more complicated methods of discrimination such as constant fraction discrimination. The discriminator may process the output from the photon detector and output an electrical pulse if a detection event such as a photon detection, afterpulse or dark count occurred. It outputs an electrical pulse if the output from the photon detector exceeds a voltage threshold. A count here refers to a successfully discriminated output signal; that is if a pulse is generated by the discriminator following an avalanche in the detector. The pulses from said discriminator 19 are sent into afterpulse separation module 20. Said afterpulse separation module 20 also has an input for light signal frequency 21. Said afterpulse separation module 20 separates pulses coinciding with light signal frequency 21 from pulses not coinciding with the light signal frequency. The afterpulse separation module provides one output 22 for pulses coinciding with the light signal frequency, and may provide a second output 23 for pulses not coinciding with the light signal frequency. In other words, the afterpulse separation module is configured to distinguish when the output signal from the photon detector corresponds to an interval or period when photons are expected.

The afterpulse separation module could be implemented with an AND gate which is a readily available component. In general it may comprise logic components configured to distinguish which pulses correspond to an illuminated gate and which pulses do not. It could for example be implemented in software on a microprocessor or FPGA (Field Programmable Gate Array).

The afterpulse separation module 20 has two inputs. One input receives the light signal frequency which indicates when photons are expected to arrive at the photon detector 17. That is, information relating to the light signal frequency is inputted into the afterpulse separation module, and indicates the times of the illuminated gates.

When the photon source 24 receives a pulse from the light signal frequency module 21 it emits a light pulse which is transmitted to the photon detector 17. A pulse from the light signal frequency module 21 is also transmitted to the afterpulse separation module 20. In some systems, the frequency of the pulses from the light signal frequency module may be reduced before transmission. In such a system, before transmission of the light signal frequency pulses, a signal divider divides the frequency to some preset divided frequency. After transmission, it is regenerated to the original frequency. The afterpulse separation module 20 will receive the pulses with the original light signal frequency which may be the regenerated signal and distinguishes when the output of the photon detector coincides with the light signal frequency pulses.

FIG. 3b shows another embodiment where the afterpulse separation 25 is implemented before the output from the detector is discriminated 26. In this system, the photon detector 17 is connected to the afterpulse separation unit 25. The output of the photon detector 17 is inputted to the afterpulse separation unit 25. When an outputted pulse from the photon detector 17 coincides with a pulse indicating the light signal frequency the afterpulse separation unit 25 outputs a pulse to discriminator 26. Where a pulse from the photon detector does not correspond to a pulse of the light signal frequency, it outputs a pulse to the discriminator 27. The afterpulse separation module in this embodiment is a switch, which sends output signals either to one or the other discriminator based on the timing information, that is based on whether it is detected in an illuminated gate or non-illuminated gate. The output of this embodiment is the same as in FIG. 3a.

FIG. 3c shows an embodiment with a master clock 120. The master clock 120 could be contained in a sending unit or a receiving unit. The master clock is connected to the light signal frequency module 21. The master clock 120 provides a clock signal to the light signal frequency module 21, which is connected to the photon source 24. The master clock 120 is also connected to the gating frequency module 18 and provides a clock signal that is used to generate the gating signal. The master clock 120 also is connected to the afterpulse separation module 20 and provides a clock signal to the afterpulse separation module 20 that is a signal containing information relating to when photons are expected to arrive at the photon detector 17. The clock signal that the master clock provides to each component may be the same frequency, and the same clock signal, or may have different frequencies.

The master clock signals are used to synchronise the photon source 24 and the photon detector 17 such that the detector gates occur when a photon is expected to arrive at the photon detector 17, and also for additional intervals when a photon is not expected to arrive at the photon detector 17. The gating frequency module 18 may be configured to generate an increased frequency signal from the master clock signal. Alternatively, the master clock signal provided to the gating frequency module 18 may have an increased frequency compared to the clock signal provided to the light signal frequency module 21. The master clock signals also synchronise the afterpulse separation module 20 such that it can distinguish between a count corresponding to a gate when a photon is expected to arrive at the detector and a count corresponding to a gate when a photon isn't expected to arrive at the detector.

The photon source 24 is connected to the photon detector 17 via a channel. This channel may be the same channel that connects, for example, the master clock 120 to the gating frequency module 18 and the afterpulse separation module 20, or it may be the same channel that connects the master clock 120 to the light signal frequency module 21. The photon source 24 emits a light pulse when it receives a pulse from the light signal frequency module 21. The photon detector 17 outputs an electrical signal in response to a detection or a dark count or an afterpulse. The photon detector is connected to a discriminator 19 which outputs a pulse if the output of the photon detector is above a threshold voltage for example. The discriminator is connected to the afterpulse separation module 20. The afterpulse separation module distinguishes between when a count from the discriminator corresponds to a gate in which a light pulse was expected and when it corresponds to a gate in which a light pulse was not expected at the photon detector. An electrical signal is output from output 22 for the first case, and output 23 for the second, for example.

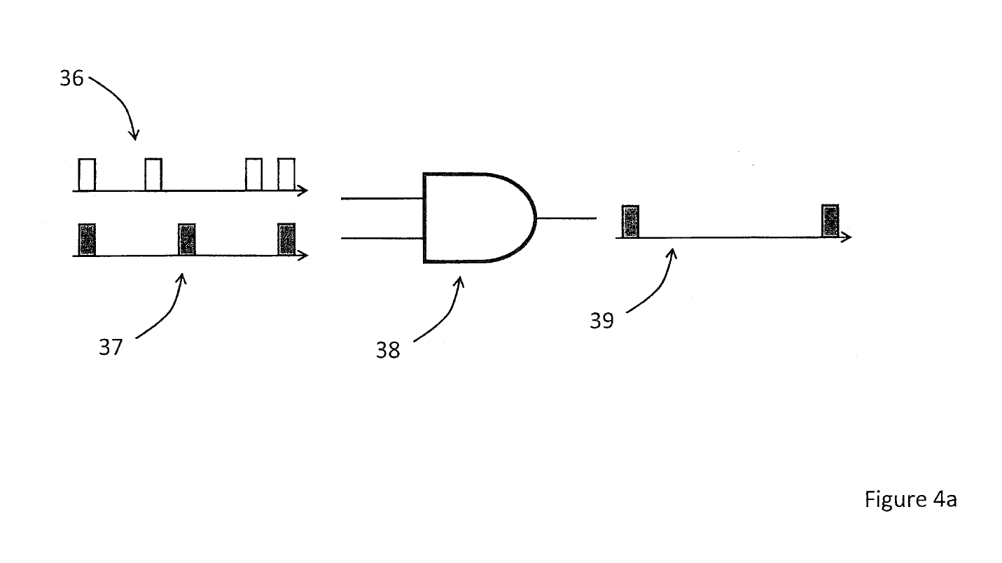

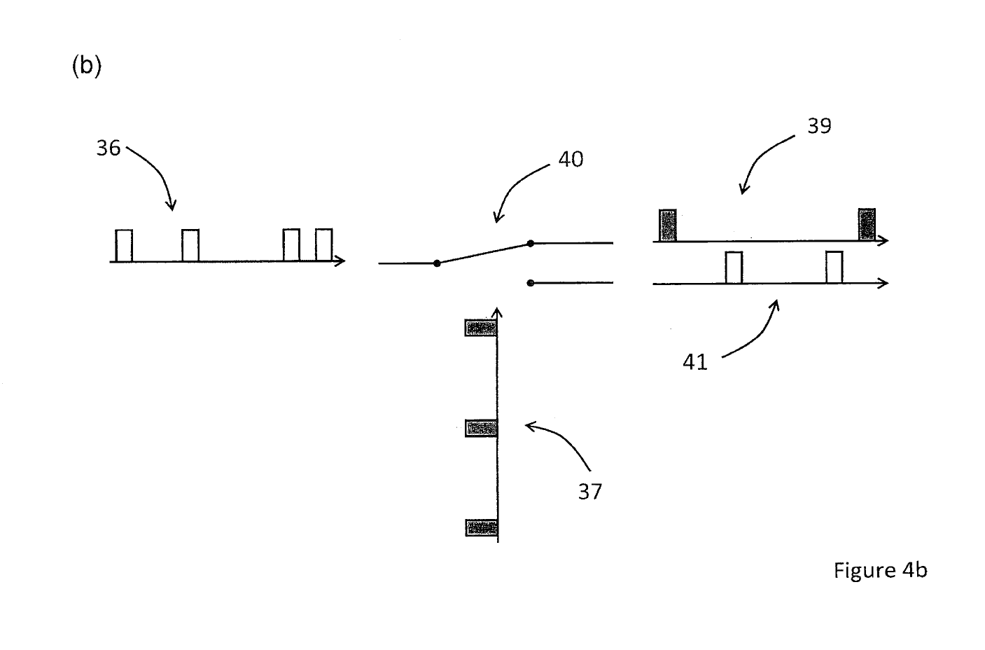

FIG. 4a is a schematic of an afterpulse separation module which is an AND gate 38. An AND gate is one of the simplest ways of building an afterpulse separation module with a single output. The AND gate 38 can be hardware based or software based. One input to the AND gate are pulses originating from counts in a gate of the photon detector 36. The other input is a periodic train of pulses with a repetition rate equal to the light signal repetition rate f_{signal} 37. Only if both are ‘high’ is a pulse generated at the output of the AND gate 39, thereby allowing to separate counts occurring in the illuminated gates from counts in the non-illuminated gates. In other words, only if there is a simultaneous pulse at both inputs 36 and 37 is a pulse generated at the output 39. All separated afterpulse counts in the extra gates are discarded in the example shown here.

FIG. 4b is a schematic of an afterpulse separation module where the separation is performed with a fast switch 40 which sends pulses to one of the two outputs depending on whether they come from illuminated or non-illuminated gates. One input is pulses originating from counts in a gate of the photon detector 36. The other input is a periodic train of pulses with a repetition rate equal to the light signal repetition rate f_{signal} 37. If both are ‘high’ a pulse is switched to the output 39. If a pulse from input 36 does not correspond to a pulse from input 37, a pulse is switched to output 41. Counts occurring in the illuminated gates are therefore separated from counts in the non-illuminated gates. In other words, only if there is a simultaneous pulse at both inputs 36 and 37 is there a pulse at the output 39. If there is a pulse at input 36 that is not simultaneous with a pulse at input 37 then there is a pulse at output 41.

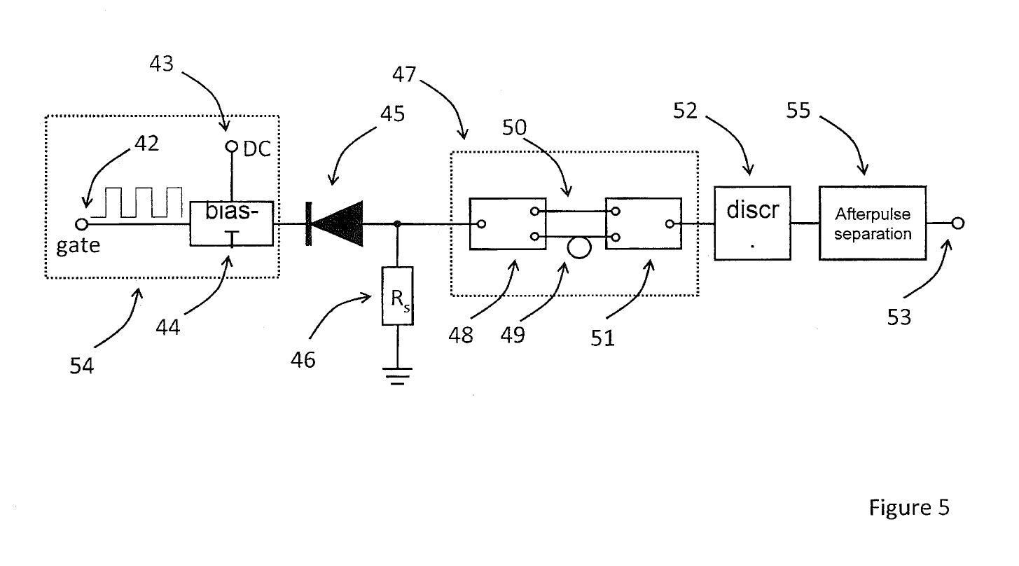

FIG. 5 shows a schematic of a photon detection system in accordance with one embodiment, with a self differencing circuit. A biasing circuit 54 comprises a DC input 43 and an AC input 42. The AC input 42 provides a gating signal for an avalanche photodiode (APD) 45. The avalanche photodiode 45 may be based on an InGaAs avalanche photodiode. The gating signal may have a frequency which is higher than the repetition rate of the photon source and may be an integer multiple of the repetition rate of the photon source. The frequency may be 10 MHz or more. The frequency may be 100 MHz or more. In one embodiment, the photon detector may operate with a detection frequency higher than 100 MHz.

DC input 43 and AC input 42 are combined at a bias-T 44. The DC level is set to a level just below the breakdown voltage of the APD 45. In combination with the AC signal the level is switched periodically above and below the breakdown voltage. The output from the biasing circuit 54 is connected to the APD 45. When the APD 45 is biased above the breakdown voltage it is in the receiving state and capable of single photon detection. The interval of time when the APD 45 is biased above the breakdown voltage is a gate. An avalanche following a photon detection leads to a voltage drop across resistor 46. This voltage drop is passed through the self-differencing circuit 47.

The self-differencing circuit 47 comprises a signal divider 48 and a signal combiner 51. The signal divider 48 and signal combiner 51 are connected via two channels 49 and 50. The self-differencing circuit 47 divides the electrical signal in signal divider 48 into two equal parts. One part is sent along channel 49 and the other part along channel 50. Output channel 49 has a delay loop which delays the electrical signal passing along this channel by an integer number of periods with respect to the electrical signal passing along channel 50. One of the electrical signals along output channel 49 and output channel 50 is then inverted and the electrical signals are combined at signal combiner 51. The inversion may take place at signal combiner 48 or signal divider 51 or during transfer. As photons will not be detected in every single gating period, by time shifting the inverted electrical signal by one period and combining the electrical signals, an output is seen which just relates to the avalanche peak. This output is then passed through a discriminator 52. The output of the discriminator 52 is connected to an afterpulse separation module 55. A pulse outputted from the discriminator 52 indicates a count. The output of the afterpulse separation module is connected to the output of the detector 53.

In the self differencing circuit, the voltage dropped across the resistor 46 is inputted into signal divider 48. Signal divider 48 divides this electrical signal into a first part and a second part which is identical to the first part. These two electrical signals are then output into two channels. The electrical signal which is output into channel 49 enters a delay line which delays it by a duration equal to an integer number of periods with respect to the electrical signal passing along channel 50. The first part and the delayed second part are then fed into signal combiner 51. Signal combiner 51 combines the first and the delayed second parts of the electrical signal. One of the electrical signals is inverted either at the signal combiner 51 or the signal divider 48 or during transfer.

When the two electrical signals are combined, periodic variations in the output of the detector are removed, in other words the capacitive response is cancelled. A positive peak followed by a negative dip (or a negative dip followed by a positive peak dependent on the configuration of the equipment) indicates an avalanche.

The self-differencing techniques use simple RF components which are AC coupled. If the input to these components has half wave symmetry such as a sine or a square wave, the output from the devices will not be distorted. This will improve the cancellation of the capacitive response of the APD and therefore make it easier to detect weak avalanches. If a gating signal with half wave symmetry is used, for example a square wave or a sine wave signal, then the RF components work well.

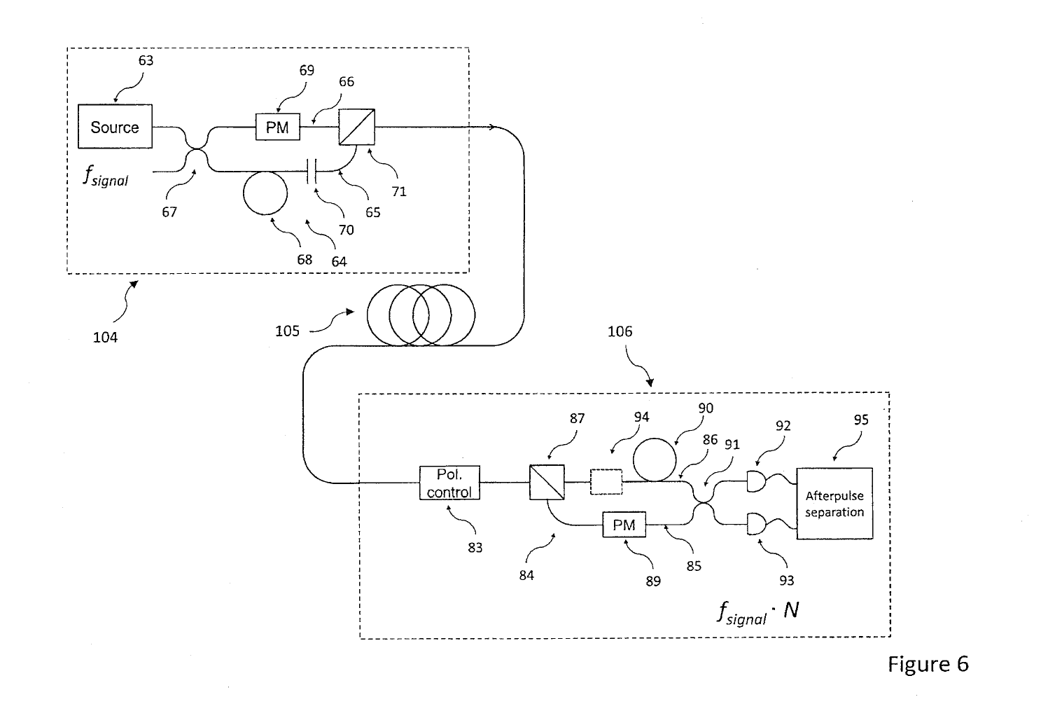

FIG. 6 is a schematic of a quantum communication system with a photon detection system in accordance with one embodiment. It is understood that any suitable quantum communication protocol could be used, an example being BB84. In this embodiment, information is encoded in the phase of the photon. However, the photon detection system and method can be used with quantum communication systems that encode information in other properties of the photon, for example polarisation.

A quantum transmitter 104 is connected to a quantum receiver 106 via a transmission line 105 which may be an optical fibre. The transmitter comprises a photon source 63, which is a periodic photon source which generates photon pulses with a repetition rate f_{signal}. The photon source 63 may be a pulsed laser diode and an attenuator. The attenuator may be set so that the average number of photons per pulse is much less than 1. Alternatively, some of the photon pulses may be sent with a different average number of photons per pulse. The photon source 63 is connected to a Mach-Zehnder interferometer 64. The photon pulses are sent through the asymmetric Mach-Zehnder interferometer 64 which encodes bit and basis information into the photon pulses using a phase modulator 69. The Mach-Zehnder interferometer has two arms 65 and 66. A polarization-maintaining beam splitter 67 at the input of the interferometer sends part of the light down arm 65 and part down arm 66. Arm 66 has a phase modulator 69. Arm 65 has a delay loop 68 which delays the light signal passing through this arm with respect to the light signal passing through arm 66. The length difference between the two arms corresponds to an optical delay. Arm 65 might also have a tuneable optical delay line 70 to fine-tune the delay between arm 65 and 66. The light signals are recombined on polarisation beam splitter 71 and then pass through the transmission line 105.

The receiver 106 comprises a polarisation controller 83. At the receiver side the light signal passes through the polarisation controller 83 which restores the initial polarisation of the light signal which might have been lost on the transmission line 105. The light signal then passes through a second asymmetric Mach-Zehnder interferometer 84 also consisting of a polarisation beam splitter 87, a polarisation-maintaining beam splitter 91, and a short 85 and a long arm 86. Arm 86 has a delay loop 90 which delays the light signal passing through this arm with respect to the light signal passing through arm 85. The length difference between the two arms corresponds to an optical delay which matches the delay of the transmitter interferometer 64 precisely. The interferometers are set up in a way such that photon pulses that travel through the short arm in interferometer 64 travel through the long arm in interferometer 84, and photon pulses that travel through the long arm in interferometer 64 travel through the short arm in interferometer 84. Both photon pulses therefore overlap again in time at the output of interferometer 84. In other words, both photon pulses arrive at the polarisation maintaining beam splitter 91 at the same time, to within the signal laser coherence time. A second phase modulator 89 is used to set the basis on the receiver side. The receiver interferometer 84 might also include a second phase shifting element 94 such as a fibre stretcher to stabilize the relative phase of the receiver interferometer 84 to the transmitter interferometer 64.

The outputs of polarisation maintaining beam splitter 91 are connected to photon detectors 92 and 93. Depending on the bit and basis chosen at the transmitter 104 and the basis chosen at the receiver 106 the light signal will either be detected in photon detector 92 or in photon detector 93. Photon detectors 92 and 93 may be gated single-photon detectors which may be based on avalanche photo-diodes and specifically may be based on InGaAs avalanche photo-diodes. The gated photon detectors may be based on a self-differencing technique. The detectors may operate with a gating frequency f signal N. The photon detectors have a frequency which is higher than the repetition rate of the photon source and may be an integer multiple of the repetition rate of the photon source. The photon detectors may operate with a detection frequency higher than 100 MHz. The afterpulse separation is performed independently for each detector in this case. The afterpulse separation module may therefore contain two separate afterpulse separation modules of the type shown in FIG. 4a or 4b, each connected to one of the detectors. There may be a single master clock input for example, which is then split to be inputted into each module.

The system shown in FIG. 6 may be synchronised using a clock signal. A clock signal may be provided to the photon source 63 by electronics. The electronics may be included in the transmitter unit 104. The electronics may comprise a timing unit, a driver for the photon source 63, a driver for a clock laser and a driver for the phase modulator 69. Photons are generated for each clock signal, encoded and sent to the receiver 106, along with a laser pulse which is the clock signal. The photon signal may be multiplexed with the clock laser signal by a WDM (wavelength division multiplexing) coupler. The clock laser may emit at a different wavelength from that of the signal laser. A WDM coupler at the receiver may be used to de-multiplex the signal into a clock signal and a photon signal.

The phase modulator 89 may be controlled with the clock signal. The photon detectors 92 and 93 may be controlled with a periodic gating signal generated from the clock signal. This periodic gating signal may have higher frequency than the clock signal frequency, thus the gating frequency of the photon detectors will be higher than the clock frequency.

Alternatively, the clock electronics may be provided in the receiver 106. The phase modulator 89 may be controlled with this clock signal or with a generated signal generated from the clock signal. The photon detectors 92 and 93 may also be controlled with the clock signal or with a generated signal generated from the clock signal. A laser pulse which is the clock signal may be transmitted to the transmitter 104 and the clock signal or a generated signal generated from the clock signal may be used to control a driver for the photon source 63 and a driver for the phase modulator 69.

There are four possible paths through the system for a light signal pulse:

### i) Long Arm 65-Long Arm 86 (Long-Long);

### ii) Short Arm 66-Long Arm 86 (Short-Long);

iii) Long Arm 65-Short Arm 85 (Long-Short); and

### iv) Short Arm 66-Short arm 85 (Short-Short).

The receiver interferometer 84 is balanced so that photon pulses taking paths (ii) and (iii) arrive at nearly the same time at the exit coupler 91 of the receiver interferometer 84. Nearly the same time means within the signal laser coherence time which is typically a few picoseconds for a semiconductor distributed feed back (DFB) laser diode.

The system can be set such that there is constructive interference at detector 92 (and thus destructive interference at detector 93) for zero phase difference between the two phase modulators. If, on the other hand, the phase difference between the modulators is 180°, there should be destructive interference at detector 92 and constructive at detector 93. For any other phase difference between the two modulators, there will be a finite probability that a photon may output at detector 92 or detector 93.

In the BB84 protocol, the voltage on phase modulator 69 is set to one of four different values, corresponding to phase shifts of 0°, 90°, 180°, and 270°. 0° and 180° are associated with bits 0 and 1 in a first encoding basis, while 90° and 270° are associated with 0 and 1 in a second encoding basis. The second encoding basis is chosen to be non-orthogonal to the first. The phase shift is chosen at random for each light signal pulse and is recorded for each clock cycle.

The voltage applied to phase modulator 89 may be randomly varied between two values corresponding to 0° and 90°. This amounts to selecting between the first and second measurement bases, respectively. The phase shift applied and the measurement result is recorded for each clock cycle.

A method of photon detection will now be described. The method involves separating afterpulse counts in a gated photon detector, where the gated photon detector is exposed to illumination during a fraction of the detector gates, the illuminated gates, and is not illuminated for the remaining gates, the non-illuminated gates, and the method involves separating the counts in the non-illuminated gates from counts in the illuminated gates. All counts in the non-illuminated gates may be discarded. The method uses a periodic photon source and a gated photon detector which may be based on an avalanche photo-diode and may be based on an InGaAs avalanche photo-diode. The gated photon detector may be based on a self-differencing technique. The gated photon detector has a frequency which is higher than the repetition rate of the photon source and may be an integer multiple of the repetition rate of the photon source. The photon detector may operate with a detection frequency higher than 100 MHz.

A method of photon detection involves generating a clock signal, and providing this clock signal to a photon source and a clock laser. The photon source generates a pulse for each pulse of the clock signal. Information is then encoded on the pulses. The clock laser also generates a pulse for each pulse of the clock signal. The encoded photon pulses are then transmitted via an optical fibre to the receiver unit. The clock laser pulses are transmitted between the receiver and the transmitter. The clock laser signal may be used to generate a periodic gating signal which is applied to the photon detector(s). This periodic gating signal is higher in frequency than the clock signal. The method comprises distinguishing when a pulse from the output of the photon detector corresponds to a pulse of a signal which indicates when the photons are expected to arrive at the gated photon detector. The signal which indicates when the photons are expected to arrive at the gated photon detector may be the clock signal.

The clock signal may be generated in the receiver unit and transmitted to the sending unit or generated in the sending unit and transmitted to the receiver unit.

A method of photon detection involves providing a photon detector configured to detect photons and applying a time varying gating signal to the photon detector. The gating signal switches the detector between a receiving state where it is more likely to detect a photon, and a non-receiving state. The gating signal switches the detector into a receiving state for intervals during which photons are expected to arrive at the detector and for additional time intervals when photons are not expected to arrive at the detector. The method further comprises distinguishing between when a count corresponds to an interval during which photons are expected to arrive at said detector and the additional intervals.

The gating signal may be periodic and have half wave symmetry, for example, the gating signal may be a sinusoidal wave or a square wave. The frequency of the gating signal may be at least 100 MHz. The frequency of the gating signal may be an integer multiple of the frequency at which photons are expected to arrive at the detector.

The method of photon detection may further provide a discriminator unit.

The photon detector provided may be but is not restricted to gated detectors based on avalanche photodiodes made of Indium Gallium Arsenide, Silicon, Germanium, or Gallium Nitride; gated detectors based on photomultiplier tubes; gated detectors based on passive quenching, active quenching, self-differencing techniques, or sine-wave gating techniques. Where the photon detector provided in the method is an APD, the photon detection system may also include a biasing circuit comprised of a DC voltage bias supply and an AC voltage bias supply configured to output an AC voltage signal which has half wave symmetry. The AC voltage signal may have an amplitude larger than 1 Volt. The method of photon detection may include setting the APD bias voltage such that it is above the APD breakdown voltage at its highest value and below the APD breakdown voltage at its lowest value during each gate period. The AC voltage may be in the form of a square wave or sinusoidal wave.

A photon detection method may involve providing a photon detector configured to detect photons and dividing the output signal of the photon detector into a first part and a second part, where the first part is substantially identical to the second part. The method may further involve delaying the second part with respect to the first part and combining the first and delayed second parts of the output signal such that the delayed second part is used to cancel periodic variations in the first part of the output signal. The photon detection method may also involve applying a periodic gating signal to the detector. The second part of the output signal may be delayed by an integer multiple of the period of the detector gating signal. One part of the output signal may be inverted with respect to the other part of the output signal prior to combining the two parts of the output signal. This combined signal may then be received by an input of an afterpulse separation module. Alternatively, the combined signal may be received by a discriminator, and the output of the discriminator may be received by an afterpulse separation module.

While certain embodiments have been described, these embodiments have been presented by way of example only, and are not intended to limit the scope of the inventions. Indeed, the novel methods and systems described herein may be embodied in a variety of other forms; furthermore, various omission, substitutions and changes in the form of the methods and systems described herein may be made without departing from the spirit of the inventions. The accompanying claims and their equivalents are intended to cover such form or modifications as would fall within the scope and spirit of the inventions.

1. A photon detection system comprising:
a photon detector, configured to detect photons during intervals when in a receiving state and to output a signal when a photon is received;
a controller, configured to generate a time varying gating signal wherein said gating signal switches said detector between the receiving state and a non-receiving state,
said controller being configured to receive and process information relating to the times photons are expected to arrive at said detector, the controller being configured to generate the gating signal such that the photon detector is in the receiving state for intervals when photons are expected and also in the receiving state for additional intervals between the intervals when the photons are expected;
a detection module, configured to distinguish between when the output signal from the photon detector corresponds to an interval when photons are expected and said additional intervals.

2. The photon detection system of claim 1, wherein said gating signal is a periodic signal and has half wave symmetry.

3. The photon detection system of claim 2, wherein said gating signal is a sinusoidal wave or a square wave.

4. The photon detection system of claim 1, wherein the frequency of the gating signal is at least 100 MHz.

5. The photon detection system of claim 1, wherein the frequency of the gating signal is an integer multiple of the frequency at which photons are expected to arrive at the detector.

6. The photon detection system of claim 1, wherein said detection module comprises:
a discriminator configured to output an electrical pulse if an inputted signal exceeds a voltage threshold.

7. The photon detection system of claim 1, wherein said detection module is configured to output a pulse when the output signal from the photon detector corresponds to an interval when photons are expected.

8. The photon detection system of claim 1, said detection module further comprising:
a first output; and
a second output; and wherein
said detection module is configured to output a pulse from said first output when the output signal from the photon detector corresponds to an interval when photons are expected and is further configured to output a pulse from said second output when the output signal from the photon detector corresponds to an additional interval.

9. The photon detection system of claim 1, wherein said photon detector is based on an avalanche photodiode.

10. The photon detection system of claim 9, wherein said avalanche photodiode comprises any one of Indium Gallium Arsenide, Silicon, Germanium, or Gallium Nitride.

11. The photon detection system of claim 9, further comprising:
a biasing circuit configured to reverse bias said avalanche photodiode, said biasing circuit comprising:
a DC voltage bias supply; and
an AC voltage bias supply.

12. The photon detection system of claim 11, wherein said AC voltage signal has an amplitude larger than 1 Volt.

13. The photon detection system of claim 11, where the APD bias voltage is above the APD breakdown voltage at its highest value and below the APD breakdown voltage at its lowest value during each gate period.

14. The photon detection system of claim 11, wherein said AC voltage bias supply is configured to output an AC voltage in the form of a square wave or sinusoidal wave.

15. The photon detection system of claim 9, further comprising:
a signal divider, configured to divide an inputted signal into a first part and a second part, where the first part is substantially identical to the second part; and
a delay means configured to delay the second part with respect to the first part by an integer multiple of the period of said gating signal; and
a combiner configured to combine the first and delayed second parts of the signal such that the delayed second part is used to cancel periodic variations in the first part.

16. A receiver for a quantum communication system, being configured to receive light pulses encoded using a basis selected from at least two bases, the receiver comprising a decoder configured to perform a measurement in a basis selected from the possible bases used to encode the pulses and a photon detection system according to claim 1, configured to receive the output of the decoder.

17. A quantum communication system, comprising:
a sending unit configured to send light pulses encoded using a basis selected from at least two bases; and
a receiver according to claim 16; and
a communication channel configured to communicate information relating to the times photons are expected to arrive at said detector between the sending unit and the receiver.

18. A method of photon detection, the method comprising:
providing a photon detector configured to detect photons when in a receiving state and to output a signal when a photon is received;
receiving and processing information relating to the times photons are expected to arrive at said detector;
generating a time varying gating signal and applying said time varying gating signal to said photon detector such that the photon detector is in the receiving state for intervals when photons are expected and also in the receiving state for additional intervals between the intervals when the photons are expected;
distinguishing between when the output signal from the photon detector corresponds to a interval when photons are expected and said additional intervals.

19. The method of claim 18, wherein said gating signal is a periodic signal with half wave symmetry.

20. The method of claim 19, wherein the frequency of the gating signal is at least 100 MHz.
